(19) United States
(12) Patent Application Publication
(10) Pub. No.: US 2019/0169735 A1
(43) Pub. Date: Jun. 6, 2019

(54) Carbon-based Nano-thin Film for Enhancing Surface Abrasion Resistance on Sapphire Thin Film

(71) Applicant: Hong Kong Baptist University, Hong Kong (HK)

(72) Inventors: Kok Wai CHEAH, Hong Kong (HK); Shing Chi TSE, Hong Kong (HK); Hoi Lam TAM, Hong Kong (HK)

(21) Appl. No.: 16/266,113

(22) Filed: Feb. 4, 2019

Related U.S. Application Data
(63) Continuation-in-part of application No. 16/252,737, filed on Jan. 21, 2019.
Application No. 16/252,737 is a continuation-in-part of application No. 15/897,166, filed on Feb. 15, 2018, now Pat. No. 10,227,689.
Application No. 15/897,166 is a continuation-in-part of application No. 16/100,186, filed on Aug. 9, 2018.
Application No. 16/252,737 is a continuation-in-part of application No. 15/897,166, filed on Feb. 15, 2018, now Pat. No. 10,227,689.
Application No. 15/897,166 is a division of application No. 15/597,170, filed on May 17, 2017, now Pat. No. 9,932,663.
Application No. 15/597,170 is a continuation-in-part of application No. 14/849,606, filed on Sep. 10, 2015, now Pat. No. 10,072,329.
Application No. 14/849,606 is a continuation-in-part of application No. 14/642,742, filed on Mar. 9, 2015, now Pat. No. 9,695,501.
Application No. 14/849,606 is a continuation-in-part of application No. 13/726,183, filed on Dec. 23, 2012, now Pat. No. 9,227,383.
Application No. 14/849,606 is a continuation-in-part of application No. 13/726,127, filed on Dec. 23, 2012, now Pat. No. 9,610,754.
Application No. 13/726,127 is a continuation-in-part of application No. 61/579,668, filed on Dec. 23, 2011.
(60) Provisional application No. 62/626,657, filed on Feb. 5, 2018.
(60) Provisional application No. 62/405,215, filed on Oct. 6, 2016.
(60) Provisional application No. 62/375,433, filed on Aug. 15, 2016.
(60) Provisional application No. 62/339,074, filed on May 19, 2016.
(60) Provisional application No. 62/183,182, filed on Jun. 22, 2015.
(60) Provisional application No. 62/049,364, filed on Sep. 12, 2014.
(60) Provisional application No. 62/049,364, filed on Sep. 12, 2014.
(60) Provisional application No. 61/579,668, filed on Dec. 23, 2011.

(51) Int. Cl. C23C 14/08; C23C 14/10; C03C 17/36; C23C 14/34; C23C 14/58; C23C 14/22; C23C 14/02; C03C 17/245; C23C 14/30; C03C 3/06

(52) U.S. Cl. CPC C23C 14/081; C03C 2217/214; C03C 17/3649; C23C 14/34; C23C 14/5806; C23C 14/221; C03C 17/3639; C03C 17/3644; C23C 14/024; C03C 17/245; C23C 14/30; C23C 14/3464; C03C 17/36; C03C 3/06; C03C 2218/32; C03C 2218/328; C03C 2218/33; C03C 2218/15; C23C 14/10

(57) ABSTRACT

The present disclosure relates to display, windows, camera cover, lens and lens cover, optical/infra-red sensors, glasses and spectacles.

### CROSS-REFERENCE TO RELATED APPLICATIONS

This application claims priority from U.S. Provisional Patent Application No. 62/626,657, filed on Feb. 5, 2018. This application is a continuation-in-part application of U.S. Non-Provisional patent application Ser. No. 16/252,737 filed Jan. 21, 2019, which is a continuation-in-part of U.S. Non-Provisional patent application Ser. No. 15/897,166 filed Feb. 15, 2018, which is a divisional application of the non-provisional patent application Ser. No. 15/597,170 filed May 17, 2017 (now patented under the U.S. Pat. No. 9,932,663), which is a continuation-in-part application of U.S. Non-provisional patent application Ser. No. 14/849,606 filed on Sep. 10, 2015 (now patented under the U.S. Pat. No. 10,072,329), which claims priority from U.S. provisional patent application No. 62/049,364 filed on Sep. 12, 2014 and U.S. provisional patent application No. 62/183,182 filed on Jun. 22, 2015 and also is a continuation-in-part application of: (1) U.S. Non-provisional patent application Ser. No. 14/642,742 filed on Mar. 9, 2015 (now patented under the U.S. Pat. No. 9,695,501) which claims priority from U.S. provisional patent application No. 62/049,364 filed on Sep. 12, 2014, (2) U.S. Non-provisional patent application Ser. No. 13/726,127 filed on Dec. 23, 2012 (now patented under the U.S. Pat. No. 9,610,754) which claims priority from U.S. provisional patent application No. 61/579,668 filed on Dec. 23, 2011, and (3) U.S. Non-provisional patent application Ser. No. 13/726,183 filed on Dec. 23, 2012 (now patented under the U.S. Pat. No. 9,227,383) which claims priority from U.S. provisional patent application No. 61/579,668 filed on Dec. 23, 2011; the non-provisional patent application Ser. No. 15/597,170 filed May 17, 2017 also claims priority from U.S. provisional patent application No. 62/339,074 filed on May 19, 2016, U.S. provisional patent application No. 62/375,433 filed on Aug. 15, 2016 and U.S. provisional patent application No. 62/405,215 filed on Oct. 6, 2016. This application is also a continuation-in-part of U.S. Non-Provisional patent application Ser. No. 15/897,166 filed Feb. 15, 2018. This application is also a continuation-in-part of U.S. Non-Provisional patent application Ser. No. 16/100,186 filed Aug. 9, 2018, which is a divisional application of U.S. Non-Provisional patent application Ser. No. 14/849,606 filed on Sep. 10, 2015. The disclosures of all the above referenced patent applications are hereby incorporated by reference in their entirety.

### FIELD OF INVENTION

The present invention relates to display, windows, camera cover, lens and lens cover, optical/infra-red sensors, glasses and spectacles incorporating a substrate with a carbon-based film that can enhance the surface abrasion resistance while a good optical transmittance is retained.

### BACKGROUND OF INVENTION

Carbon is a polymorphic material; it can exist in many crystal forms which give different electrical, optical and mechanical properties. For example, carbon in the form of graphite is electrically conductive and also acts as lubricant. In another example, carbon in the form of diamond is the hardest known material on Earth. More exotic and novel carbon forms such as C60, Carbon Nano-Tube (CNT), graphene and Diamond Like Carbon (DLC) have been developed over the last two decades and their potential applications have yet been fully explored.

As mentioned above, graphite can act as lubricant; so are several other carbon forms such as graphene, DLC and CNT. They are mechanically robust and act as surface lubricant to reduce any frictional loss. However, the optical transmittance of these carbon-based films is low; when the film thickness is above certain critical thickness, e.g. 50 nm for DLC, the transmission drops and the films exhibit tinted colour. Therefore, they are not suitable for applications where good optical transmittance, e.g., at least 80%, is also required. However, at sub-100 nm thickness the transmission is likely at a more acceptable level.

Graphite and DLC can be prepared using Physical Vapour Deposition (PVD) methods such as sputtering whereas graphene and CNT can be prepared from using sputtering followed by various form of chemical vapour deposition (CVD). They can deposited onto several types of substrate such as glass, quartz, fused silica and metals.

An objective of the current invention is to invent a very thin film functional carbon coating that performs as both a lubricant and anti-scratch surface on other thin film surfaces such that the very thin film functional carbon coating retains the optical transmission of the surfaces being coated.

Citation or identification of any reference in this section or any other section of this application shall not be construed as an admission that such reference is available as prior art for the present application.

### SUMMARY OF INVENTION

In one first aspect of the present invention there is presented a method of enhancing surface abrasion resistance on a substrate comprising depositing a carbon-based film with a thickness of no more than 100 nm on to said substrate such that the carbon-based film deposited substrate has an optical transmittance of at least 70%.

In a first embodiment of the first aspect of the present invention there is presented a method of enhancing surface abrasion resistance on a substrate wherein the substrate comprises glass, quartz, fused silica, metals and sapphire.

In a second embodiment of the first aspect of the present invention there is presented a method of enhancing surface abrasion resistance on a substrate wherein said depositing comprises physical vapor deposition and/or chemical vapor deposition.

In a third embodiment of the first aspect of the present invention there is presented a method of enhancing surface abrasion resistance on a substrate wherein the physical vapor deposition comprises DC sputtering, RF sputtering, thermal evaporation, and e-beam evaporation, and wherein said chemical vapor deposition is plasma enhanced chemical vapor deposition.

In a fourth embodiment of the first aspect of the present invention there is presented a method of enhancing surface abrasion resistance on a substrate wherein said deposition is carried out in a temperature from about room temperature to about 800° C.

In a fifth embodiment of the first aspect of the present invention there is presented a method of enhancing surface abrasion resistance on a substrate wherein said carbon-based film comprises one or more of C60, carbon nano-tube, graphene, graphite, diamond-like carbon, and/or metal.

In a sixth embodiment of the first aspect of the present invention there is presented a method of enhancing surface abrasion resistance on a substrate wherein the carbon-based film comprises graphite and metal in which the metal is deposited as a precursor to enhance adhesion between the substrate and the carbon-based film, such that the thickness ratio between the metal layer and the carbon-based film layer is no more than 1:10 and wherein the metal is deposited by physical vapor deposition comprising DC sputtering, RF sputtering and e-beam evaporation, and wherein said metal comprises aluminium, silver, chromium, titanium, and magnesium, and wherein said metal is deposited at a temperature from about room temperature to 900° C.

In a seventh embodiment of the first aspect of the present invention there is presented a method of enhancing surface abrasion resistance on a substrate wherein the carbon-based film deposited sapphire has a hardness of up to 9.5 mohs.

In an eighth embodiment of the first aspect of the present invention there is presented a method of enhancing surface abrasion resistance on a substrate wherein the carbon-based film deposited substrate has an optical transmittance of 70-99%.

In a ninth embodiment of the first aspect of the present invention there is presented a method of enhancing surface abrasion resistance on a substrate wherein the thickness of the carbon-based film is less than 30 nm.

A sapphire film coated substrate prepared by the method of the first aspect of the present invention.

Throughout this specification, unless the context requires otherwise, the word “include” or “comprise” or variations such as “includes” or “comprises” or “comprising”, will be understood to imply the inclusion of a stated integer or group of integers but not the exclusion of any other integer or group of integers. It is also noted that in this disclosure and particularly in the claims and/or paragraphs, terms such as “included”, “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the specification and claims, unless the context requires otherwise, the word “include” or variations such as “includes” or “including”, will be understood to imply the inclusion of a stated integer or group of integers but not the exclusion of any other integer or group of integers.

Other definitions for selected terms used herein may be found within the detailed description of the present invention and apply throughout. Unless otherwise defined, all other technical terms used herein have the same meaning as commonly understood to one of ordinary skill in the art to which the present invention belongs.

Other aspects and advantages of the present invention will be apparent to those skilled in the art from a review of the ensuing description.

### BRIEF DESCRIPTION OF DRAWINGS

The above and other objects and features of the present invention will become apparent from the following description of the present invention, when taken in conjunction with the accompanying drawings, in which:

FIG. 1 shows the transmittance of carbon film as a function of film thickness.

FIG. 2 shows the optical transmission properties of DLC.

FIG. 3 shows the DLF film hardness

FIG. 4 shows the nanoindentation results of graphite film on sapphire film comparing it with other films/materials.

### DETAILED DESCRIPTION OF THE INVENTION

This invention is to deposit a sub-100 nm thick carbon-based film on to patented sapphire film (U.S. Pat. No. 9,695,501 B2; U.S. Pat. No. 10,072,329B2, U.S. Pat. No. 9,932,663B2) to enhance the surface smoothness. This invention can also be deposited onto other thin film surfaces. The carbon film is to act as a layer of lubricant on the sapphire film that is sufficiently hard to resist direct scratching. However, its hardness and surface roughness can cause marks being made on the surface, giving an impression of being scratched. The carbon film will reduce the scratching friction thus eliminate any markings. The carbon-based film has an added advantage of further enhancing the sapphire film hardness.

The following is an example of the present method, including the steps of:
1. A layer of 1-100 nm thick carbon-based film is deposited onto a sapphire film using PVD methods. The sapphire film is prepared according to US patents: U.S. Pat. No. 9,695,501 B2; U.S. Pat. No. 10,072,329 B2, U.S. Pat. No. 9,932,663 B2.
2. The deposition methods can be one of the PVD methods such as DC sputtering, RF sputtering thermal evaporation, and e-beam evaporation.
3. The deposition of carbon-based film can be done at room temperature (or 25° C.) and up to 800° C.
4. The material(s) of carbon-based film can be graphite, metal plus graphite in which metal is deposited as a precursor that can enhance adhesion between the sapphire film and the carbon-based film.
5. The metals can be deposited by one of the PVD methods such as DC sputtering, RF sputtering and e-beam.
6. Metals can be Al, Ag, Cr, Ti and Mg but exclusive these.
7. The metal ‘layer thickness’ is ranged from 1 to 30 nm. The ratio of thickness of the metal layer to the carbon-based film is no more than 1:10.
8. The deposition of metal can be done at room temperature and up to 900° C.
9. The deposited carbon-based film together with the sapphire film can have hardness up to 9.5 mohs.
10. The optical transmission of the deposited carbon-based film together with the sapphire film is in the range of 70-99%.

Graphite film was deposited onto sapphire film and the hardness of the bilayer was measured. Its hardness is compared to other materials as well as the sapphire film itself. No obvious enhancement in hardness was observed but there is also no degradation of the hardness of the sapphire film (Table 1).

Table 1 Hardness of graphite film on sapphire film comparing it to the hardness of other materials/films.

Hardness

| | GPa at 50 nm | Mohs |
|---|---|---|
| Sapphire | 37.15 | 8.9 |
| Al2O3 film | 10.74 | 6.3 |
| Carbon film on Al2O3 film | 9.47 | 6 |
| Quartz | 15.36 | 7 |
| Bare Soda-lime Glass | 6.37 | 5.2 |

Deposition of DLC onto Sapphire Film

The base material, or substrate, can be a sapphire film coated glass/plastic/metal (U.S. Pat. No. 9,695,501 B2; U.S. Pat. No. 10,072,329 B2, U.S. Pat. No. 9,932,663 B2). Deposition methods are CVD and PVD, the latter is more environmentally friendly.

For PVD, RF sputtering is preferred method, although other methods such as thermal evaporation, e-beam and CVD, these methods can deposit a range of carbon-based films, including graphite, DLC, carbon nanotube and graphene. Each of these methods has its specific advantage in depositing one or two types of carbon-based films and thus they can be selectively used to deposit the desired type. For examples, graphite film can be deposited by thermal deposition, sputtering and CVD are used more for DLC deposition etc.

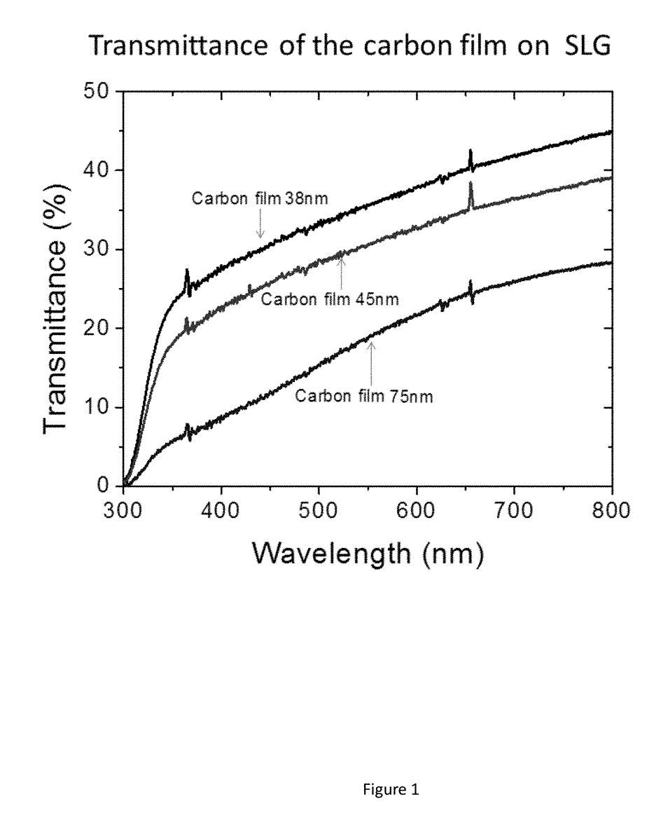

Carbon-based films are not optically transparent when they are too thick. FIG. 1 shows optical transmission as a function of graphite film thickness. The result show that film thickness greater than 30 nm has low optical transmission and is not desirable for certain applications such as anti-scratch film for display. Different types of carbon-based film have different transmission characteristics.

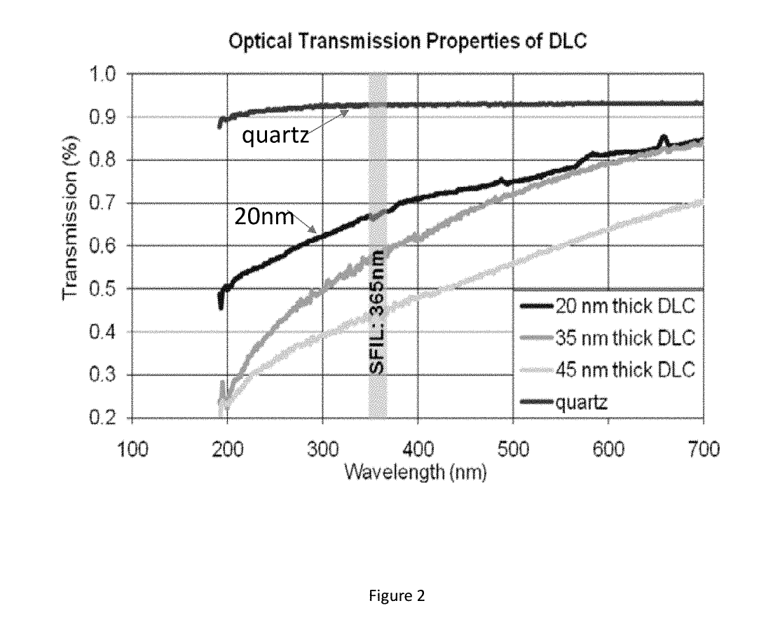

For example, in FIG. 2, DLC film deposited by using PECVD (plasma enhanced chemical vapour deposition) shows a clear transmission variation with respect to film thickness. In DLC structure, the transmission has improved; for a @35 nm thick film at 400 nm, the transmission of DLC is about 60% whereas for a graphite film the transmission is only about 28%. Therefore, in terms of optical applications DLC is preferred.

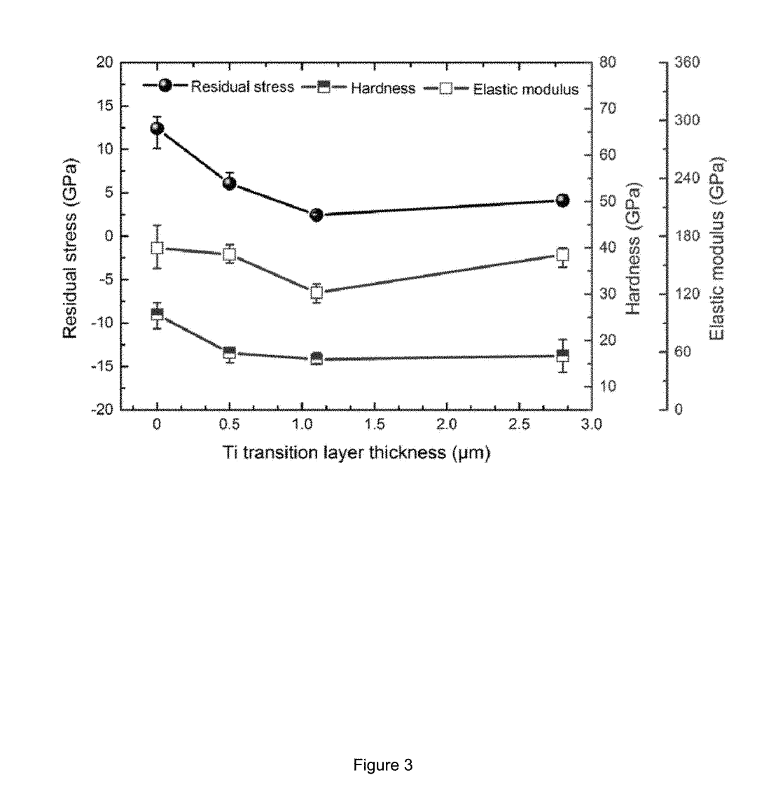

DLC also has better mechanical property than graphite film; it is harder; in fact its hardness is getting close to that of sapphire single crystal. At about 200 nm DLC has a hardness of about 22 GPa viz 8 mho. This hardness will increase further when DLC is deposited onto a sapphire film bringing the total hardness close to 9 mho. It would mean that hardness of the DLC/sapphire film prepared at room temperature will have an enhanced hardness (FIG. 3).

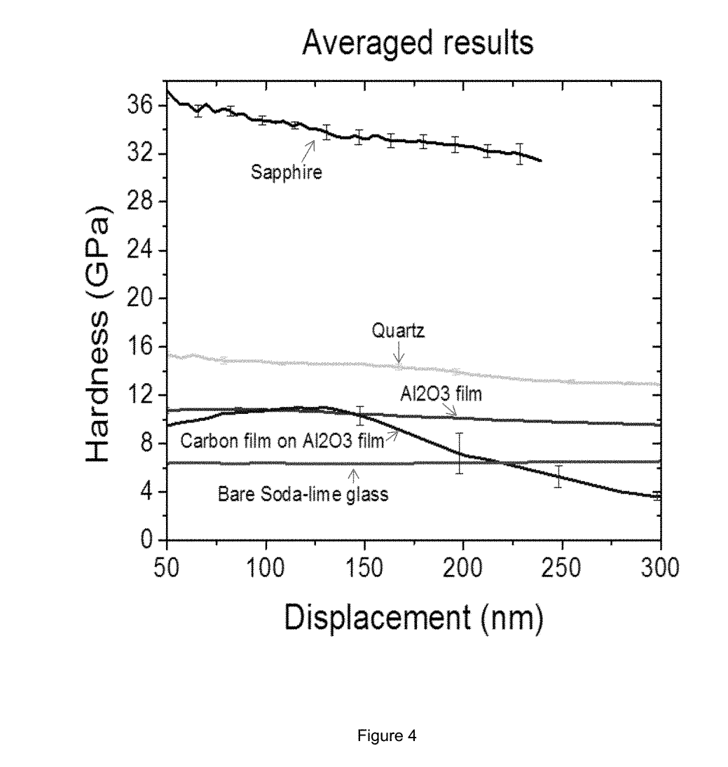

The hardness of graphite film deposited onto sapphire film was measured and is shown in FIG. 4. The enhancement is not as obvious as that of DLC on sapphire film but it does show that overall there is no degradation of hardness.

1. A method of enhancing surface abrasion resistance on a substrate comprising depositing a carbon-based film with a thickness of no more than 100 nm on to said substrate such that the carbon-based film deposited substrate has an optical transmittance of at least 70%.

2. The method of claim 1, wherein the substrate comprises glass, quartz, fused silica, metals and sapphire.

3. The method of claim 1, wherein said depositing comprises physical vapor deposition and/or chemical vapor deposition.

4. The method of claim 3, wherein the physical vapor deposition comprises DC sputtering, RF sputtering, thermal evaporation, and e-beam evaporation.

5. The method of claim 3, wherein said chemical vapor deposition is plasma enhanced chemical vapor deposition.

6. The method of claim 1, wherein said deposition is carried out in a temperature from about room temperature to about 800° C.

7. The method of claim 1, wherein said carbon-based film comprises one or more of C60, carbon nano-tube, graphene, graphite, diamond-like carbon, and/or metal.

8. The method of claim 7, wherein the carbon-based film comprises graphite and metal in which the metal is deposited as a precursor to enhance adhesion between the substrate and the carbon-based film, and wherein the thickness ratio between the metal layer and the carbon-based film is no more than 1:10.

9. The method of claim 7, wherein the metal is deposited by physical vapor deposition comprising DC sputtering, RF sputtering and e-beam evaporation.

10. The method of claim 7 wherein said metal comprises aluminium, silver, chromium, titanium, and magnesium.

11. The method of claim 7, wherein said metal is deposited at a temperature from about room temperature to 900° C.

12. The method of claim 2, wherein the carbon-based film deposited sapphire has a hardness of up to 9.5 mohs.

13. The method of claim 1, wherein the carbon-based film deposited substrate has an optical transmittance of 70-99%.

14. The method of claim 1, wherein the thickness of the carbon-based film is less than 30 nm.

15. A sapphire film coated substrate prepared by the method of claim 1.
